(19) United States
(12) Patent Application Publication
(10) Pub. No.: US 2025/0227955 A1
(43) Pub. Date: Jul. 10, 2025

(54) FIELD EFFECT TRANSISTOR AND MANUFACTURING METHOD OF THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Ryota SUZUKI, Nisshin-shi (JP)

(21) Appl. No.: 18/959,932

(22) Filed: Nov. 26, 2024

(30) Foreign Application Priority Data
Jan. 9, 2024 (JP) 2024-001457

(51) Int. Cl. H01L 29/78; H01L 29/06; H01L 29/66

(52) U.S. Cl. CPC H10D 30/668; H10D 30/0297; H10D 62/124

(57) ABSTRACT

A field effect transistor includes a semiconductor substrate including a source region, a body region, a lower n-type region, an electric field relaxation region and a pillar region, a gate insulating film and a gate electrode disposed in a trench on an upper surface of the semiconductor substrate, and a source electrode. The pillar region includes a contact region and a connection region. The contact region is in contact with the source electrode and has a p-type impurity concentration higher than that of a body region. The connection region extends from a lower end of the contact region to a position in contact with the electric field relaxation region, and has a p-type impurity concentration lower than that of the contact region and higher than that of the body region. A boundary between the contact region and the connection region is located above a lower end of the body region.

### CROSS REFERENCE TO RELATED APPLICATION

The present application claims the benefit of priority from Japanese Patent Application No. 2024-001457 filed on Jan. 9, 2024. The entire disclosure of the above application is incorporated herein by reference.

### TECHNICAL FIELD

The present disclosure relates to a field effect transistor and a manufacturing method of the same.

### BACKGROUND

There has been known a field effect transistor including a trench-type gate electrode and an electric field relaxation region that relaxes an electric field at a lower end of a trench.

### SUMMARY

The present disclosure provides a field effect transistor that includes a semiconductor substrate having an upper surface and a lower surface opposite to the upper surface, and having at least one trench provided from the upper surface, a gate insulating film and a gate electrode disposed in the at least one trench, and a source electrode in contact with the upper surface of the semiconductor substrate. The semiconductor substrate includes a source region of n-type in contact with the gate insulating film and the source electrode, a body region of p-type in contact with the gate insulating film at a position below the source region, a lower n-type region in contact with the body region from below, in contact with the gate insulating film at a position below the body region, and extending to a position below a lower end of the at least one trench, an electric field relaxation region of p-type disposed within a depth range including the lower end of the at least one trench or within a depth range below the lower end of the at least one trench, and in contact with the lower n-type region, and a pillar region of p-type extending in a depth direction from a position in contact with the source electrode to a position in contact with the electric field relaxation region. The pillar region includes a contact region of p-type disposed at a position in contact with the source electrode and having a p-type impurity concentration higher than a p-type impurity concentration of the body region, and a connection region of p-type extending from a lower end of the contact region to a position in contact with the electric field relaxation region, and having a p-type impurity concentration that is lower than the p-type impurity concentration of the contact region and higher than the p-type impurity concentration of the body region. A boundary between the contact region and the connection region is located above a lower end of the body region.

The present disclosure also provides a manufacturing method of the field effect transistor. The manufacturing method includes forming the contact region by implanting a p-type impurity into the semiconductor substrate through a mask, and forming the connection region by implanting a p-type impurity into the semiconductor substrate through the mask that is used for the forming of the contact region.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional perspective view of a field effect transistor according to a first embodiment;

FIG. 2 is a cross-sectional view along an xz plane of the field effect transistor according to the first embodiment;

FIG. 3 is a plan view showing the arrangement of trenches, pillar regions, and electric field relaxation regions when the field effect transistor of the first embodiment is viewed from above;

FIG. 4 is a graph showing a p-type impurity concentration distribution on a center line CL;

FIG. 5 is a diagram illustrating a manufacturing method of the field effect transistor according to the first embodiment;

FIG. 6 is a diagram illustrating the manufacturing method of the field effect transistor according to the first embodiment;

FIG. 7 is a diagram illustrating the manufacturing method of the field effect transistor according to the first embodiment;

FIG. 8 is a diagram illustrating the manufacturing method of the field effect transistor according to the first embodiment;

FIG. 9 is a cross-sectional view taken along an xz plane of a field effect transistor according to a second embodiment;

FIG. 10 is a cross-sectional view taken along an xz plane of a field effect transistor according to a third embodiment;

FIG. 11 is a cross-sectional view taken along an xz plane of a field effect transistor according to a fourth embodiment;

FIG. 12 is a cross-sectional perspective view of a field effect transistor according to a fifth embodiment;

FIG. 13 is a plan view showing the arrangement of trenches, pillar regions, and electric field relaxation regions when the field effect transistor according to the fifth embodiment is viewed from above;

FIG. 14 is a cross-sectional perspective view of a field effect transistor according to a sixth embodiment;

FIG. 15 is a plan view showing the arrangement of trenches, pillar regions, and electric field relaxation regions when the field effect transistor according to the sixth embodiment is viewed from above; and

FIG. 16 is a cross-sectional view taken along an xz plane of a field effect transistor according to a seventh embodiment.

### DETAILED DESCRIPTION

In a field effect transistor, an electric field relaxation region may be disposed so as to be in contact with a lower end of a trench, or may be disposed at a position away from the lower end of the trench. When the field effect transistor is turned off, a depletion layer spreads from the electric field relaxation region to its surroundings, thereby relaxing an electric field at the lower end of the trench.

A field effect transistor according to a related art includes a contact region, a body region (also called a base region), and a connection region. The contact region has a high p-type impurity concentration and is in contact with a source electrode. The body region is disposed below the contact region. The body region is a region where a channel is formed when the field effect transistor is turned on, and therefore a p-type impurity concentration in the body region is low. The connection region is disposed below the body region and connects the body region to an electric field relaxation region. The connection region has a higher p-type impurity concentration than the body region. The electric field relaxation region is connected to the source electrode via the connection region, the body region, and the contact region. Since the p-type impurity concentration in the body region is low, an electrical resistance of the body region is high. Since the body region, which has a high electrical resistance, is disposed between the connection region and the contact region, an electrical resistance of a path connecting the electric field relaxation region to the source electrode is high. Therefore, a potential of the electric field relaxation region is unstable. Furthermore, by forming the contact region deep so that the contact region penetrates the body region, the electrical resistance of the path connecting the electric field relaxation region to the source electrode can be reduced. However, when forming the contact region having a high p-type impurity concentration deep, crystal defects increase in a semiconductor substrate, making leakage current more likely to occur.

A field effect transistor according to a first aspect of the present disclosure includes a semiconductor substrate having an upper surface and a lower surface opposite to the upper surface, and having at least one trench provided from the upper surface, a gate insulating film and a gate electrode disposed in the at least one trench, and a source electrode in contact with the upper surface of the semiconductor substrate. The semiconductor substrate includes a source region of n-type in contact with the gate insulating film and the source electrode, a body region of p-type in contact with the gate insulating film at a position below the source region, a lower n-type region in contact with the body region from below, in contact with the gate insulating film at a position below the body region, and extending to a position below a lower end of the at least one trench, an electric field relaxation region of p-type disposed within a depth range including the lower end of the at least one trench or within a depth range below the lower end of the at least one trench, and in contact with the lower n-type region; and a pillar region of p-type extending in a depth direction from a position in contact with the source electrode to a position in contact with the electric field relaxation region. The pillar region includes a contact region of p-type disposed at a position in contact with the source electrode and having a p-type impurity concentration higher than a p-type impurity concentration of the body region, and a connection region of p-type extending from a lower end of the contact region to a position in contact with the electric field relaxation region, and having a p-type impurity concentration that is lower than the p-type impurity concentration of the contact region and higher than the p-type impurity concentration of the body region. A boundary between the contact region and the connection region is located above a lower end of the body region.

A manufacturing method according to a second aspect of the present disclosure is a manufacturing method of the field effect transistor according to the first aspect and includes forming the contact region by implanting a p-type impurity into the semiconductor substrate through a mask, and forming the connection region by implanting a p-type impurity into the semiconductor substrate through the mask that is used for the forming of the contact region.

In the field effect transistor, there is no body region with a low p-type impurity concentration between the contact region and the connection region, and the contact region and the connection region are in contact with each other. Thus, the electric field relaxation region is connected to the source electrode via the connection region and the contact region. Therefore, an electrical resistance of a path connecting the electric field relaxation region to the source electrode is low, and a potential of the electric field relaxation region is stable. Furthermore, since the boundary between the contact region and the connection region is located above the lower end of the body region, the contact region having a high p-type impurity concentration is disposed within a shallow range in the vicinity of the upper surface of the semiconductor substrate. Therefore, the semiconductor substrate has few crystal defects, and leakage current is unlikely to occur. Thus, with this configuration, the electrical resistance of the path connecting the electric field relaxation region to the source electrode can be suitably reduced.

### First Embodiment

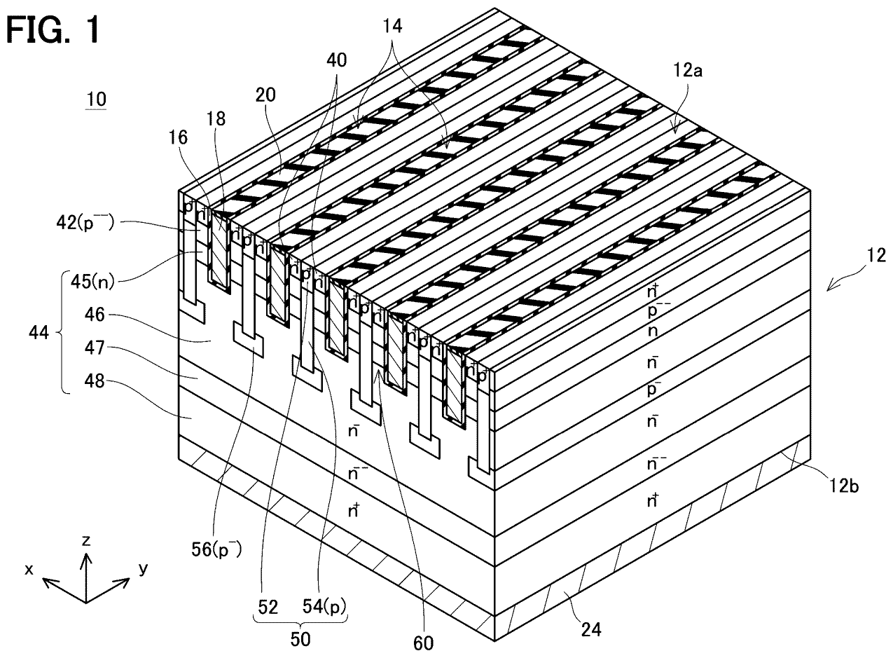

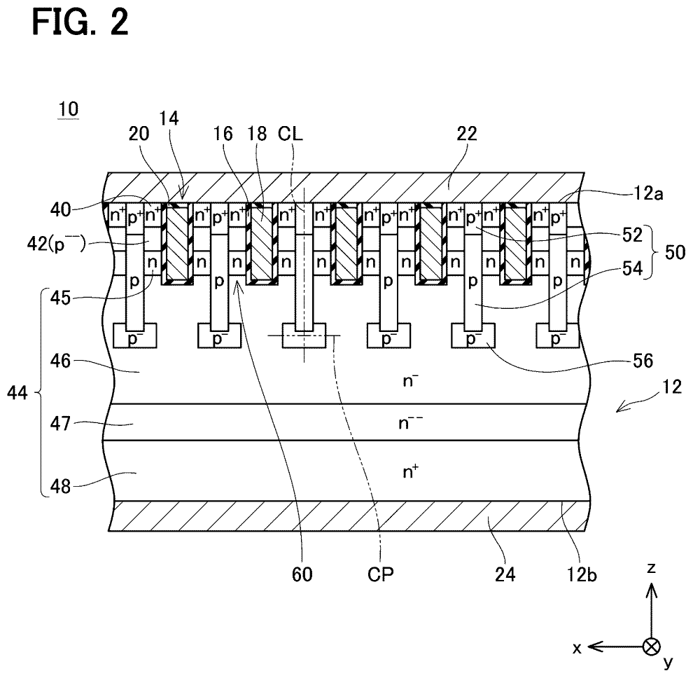

As shown in FIG. 1 and FIG. 2, a field effect transistor 10 according to a first embodiment includes a semiconductor substrate 12. The semiconductor substrate 12 is made of SiC. However, the semiconductor substrate 12 may be made of other semiconductor materials (for example, Si, GaN, Ga₂O₃, and the like). In the following, a thickness direction of the semiconductor substrate 12 may also be referred to as a z direction, a direction parallel to an upper surface 12a of the semiconductor substrate 12 may also be referred to as an x direction, a direction parallel to the upper surface 12a and perpendicular to the x direction may also be referred to as a y direction.

The semiconductor substrate 12 has a plurality of trenches 14 provided from the upper surface 12a. On the upper surface 12a, each of the trenches 14 extends linearly in the y direction. The trenches 14 are arranged at intervals in the x direction. In each of the trenches 14, a gate insulating film 16 and a gate electrode 18 are disposed. The gate insulating film 16 covers an inner surface of each of the trenches 14. The gate electrode 18 is insulated from the semiconductor substrate 12 by the gate insulating film 16. An upper surface of the gate electrode 18 is covered with an interlayer insulating film 20. As shown in FIG. 1, in the vicinity of the upper surface 12a of the semiconductor substrate 12, a semiconductor region is partitioned into a plurality of semiconductor regions by the trenches 14. Hereinafter, each of the semiconductor regions partitioned by the trenches 14 (that is, each of the semiconductor regions sandwiched between the trenches 14) will be referred to as a partitioned region 60.

The field effect transistor 10 has a source electrode 22 and a drain electrode 24. The source electrode 22 covers the upper surface 12a of the semiconductor substrate 12. The source electrode 22 is insulated from the gate electrode 18 by the interlayer insulating film 20. The drain electrode 24 covers a lower surface 12b of the semiconductor substrate 12 that is opposite to the upper surface 12a.

The semiconductor substrate 12 has a source region 40, a body region 42, a lower n-type region 44, a plurality of pillar regions 50, and a plurality of electric field relaxation regions 56.

The source region 40 is an n-type region and has a high n-type impurity concentration. The source region 40 is disposed within the partitioned region 60. The source region 40 is disposed in a range including the upper surface 12a, and is in ohmic contact with the source electrode 22. The source region 40 is in contact with the gate insulating film 16 on a side surface of the trench 14.

The body region 42 is a p-type region and has a low p-type impurity concentration. The body region 42 is disposed within the partitioned region 60. The body region 42 is disposed below the source region 40 and is in contact with the source region 40 from below. The body region 42 is in contact with the gate insulating film 16 on the side surface of the trench 14 at a position below the source region 40.

The lower n-type region 44 is disposed below the body region 42. The lower n-type region 44 is distributed from a position in contact with the body region 42 to the lower surface 12b of the semiconductor substrate 12. The lower n-type region 44 includes a current dispersion region 45, a junction field effect transistor (JFET) region 46, a drift region 47 and a drain region 48.

The current dispersion region 45 has a medium n-type impurity concentration. The current dispersion region 45 is disposed within the partitioned region 60. The current dispersion region 45 is disposed below the body region 42 and is in contact with the body region 42 from below. The current dispersion region 45 is in contact with the gate insulating film 16 on the side surface of the trench 14 at a position below the body region 42. The current dispersion region 45 corresponds to a first n-type region.

The JFET region 46 is an n-type region having a lower n-type impurity concentration than the current dispersion region 45. The JFET region 46 is distributed from within each of the partitioned regions 60 across a region below each of the partitioned regions 60. The JFET region 46 is disposed below the current dispersion region 45 and is in contact with the current dispersion region 45 from below. The JFET region 46 is in contact with the gate insulating film 16 at a position below the current dispersion region 45. The JFET region 46 corresponds to a second n-type region.

The drift region 47 is an n-type region having a lower n-type impurity concentration than the JFET region 46. The drift region 47 is disposed below the JFET region 46 and is in contact with the JFET region 46 from below.

The drain region 48 is an n-type region having a higher n-type impurity concentration than the current dispersion region 45. The drain region 48 is disposed below the drift region 47 and is in contact with the drift region 47 from below. The drain region 48 is in ohmic contact with the drain electrode 24 at the lower surface 12b.

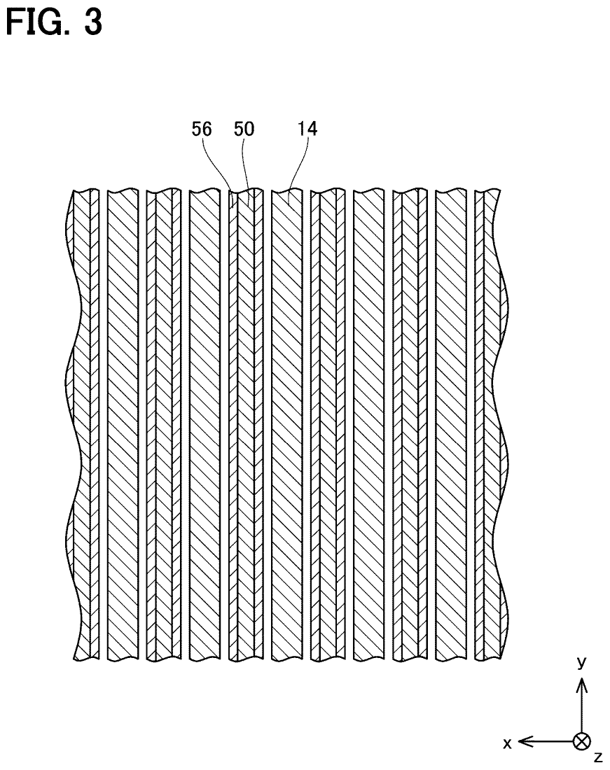

Each of the electric field relaxation regions 56 is a p-type region, and is disposed within a depth range below the lower end of the trench 14. Each of the electric field relaxation regions 56 is disposed at a position surrounded by the JFET region 46 and is in contact with the JFET region 46. Each of the electric field relaxation regions 56 is disposed below each of the partitioned regions 60 (more specifically, below the center in the x direction of each of the partitioned regions 60). The width of each of the electric field relaxation regions 56 in the x direction is greater than the width of each of the pillar regions 50 in the x direction. FIG. 3 shows the arrangement of the trenches 14, the pillar regions 50, and the electric field relaxation regions 56 when the semiconductor substrate 12 is viewed from above. In FIG. 3, the pillar regions 50 overlaps with the electric field relaxation regions 56. As shown in FIG. 1 and FIG. 3, each of the electric field relaxation regions 56 extends linearly in the y direction.

The pillar regions 50 are p-type regions and are disposed within the respective partitioned regions 60. Each of the pillar regions 50 is disposed at the center of the corresponding partitioned region 60 in the x direction. Each of the pillar regions 50 extends in the z direction from a position in contact with the source electrode 22 to a position in contact with the corresponding electric field relaxation region 56. Each of the pillar regions 50 penetrates through the source region 40 and the body region 42. As shown in FIG. 1 and FIG. 3, each of the pillar regions 50 extends linearly in the y direction. Each of the pillar regions 50 includes a contact region 52 and a connection region 54.

The contact region 52 is an upper portion of the pillar region 50 and has a high p-type impurity concentration. The contact region 52 extends in the z direction from a position in contact with the source electrode 22 to a depth range of the body region 42. The depth range of the body region 42 means a depth range between an upper end and a lower end of the body region 42. That is, the contact region 52 penetrates the source region 40. The p-type impurity concentration of the contact region 52 is higher than the n-type impurity concentration of the source region 40.

The connection region 54 is a lower portion of the pillar region 50 and has a p-type impurity concentration lower than that of the contact region 52 and higher than that of the body region 42. The p-type impurity concentration of the connection region 54 is higher than the n-type impurity concentration of the current dispersion region 45, that is, the first n-type region. The connection region 54 extends in the z direction from a position in contact with a lower end of the contact region 52 to the electric field relaxation region 56. A boundary between the contact region 52 and the connection region 54 is located within the depth range of the body region 42, that is, above the lower end of the body region 42.

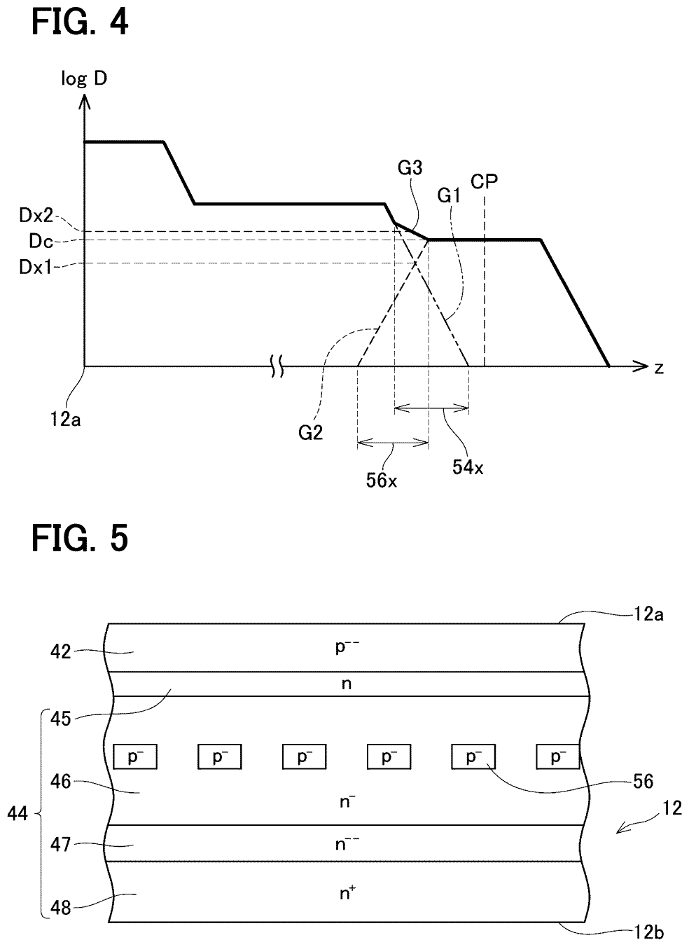

A graph G3 in FIG. 4 shows a distribution of a p-type impurity concentration D on a center line CL (see FIG. 2) of the pillar region 50 in the x direction. FIG. 4 shows the distribution of the p-type impurity concentration on a path from a center position CP in the z direction of the electric field relaxation region 56 to the upper surface 12a (that is, the source electrode 22). The vertical axis in FIG. 4 is expressed in logarithm. As shown in FIG. 4, at any position on the path from the center position CP to the source electrode 22, the p-type impurity concentration is higher than a p-type impurity concentration Dc at the center position CP. Therefore, the electrical resistance is low over the entire path from the electric field relaxation region 56 to the source electrode 22.

Next, the operation of the field effect transistor 10 will be described. When the field effect transistor 10 is in use, a higher potential is applied to the drain electrode 24 as compared to the source electrode 22. When a potential equal to or higher than a gate threshold value is applied to the gate electrode 18, a channel is formed at a portion of the body region 42 in the vicinity of the gate insulating film 16, and the source region 40 is connected to the current dispersion region 45 by the channel. Then, electrons flow from the source electrode 22 through the source region 40, the channel, the current dispersion region 45, the JFET region 46, the drift region 47 and the drain region 48 to the drain electrode 24. Since the current dispersion region 45 having a relatively high n-type impurity concentration is disposed below the body region 42, electrons that flow from the channel into the current dispersion region 45 tend to diffuse in the x direction within the current dispersion region 45. Therefore, electrons can flow in a dispersed manner within the lower n-type region 44. Accordingly, the on-resistance of the field effect transistor is reduced.

When the potential of the gate electrode 18 is reduced to a value lower than the gate threshold value, the channel disappears and the field effect transistor 10 is turned off. Then, a reverse voltage is applied to a pn junction at an interface between the body region 42 and the lower n-type region 44, and a depletion layer spreads in the current dispersion region 45, the JFET region 46, and the drift region 47. Furthermore, since the electric field relaxation region 56 is connected to the source electrode 22 by the pillar region 50, a reverse voltage is also applied to a pn junction at an interface between the electric field relaxation region 56 and the JFET region 46 when the field effect transistor 10 is turned off. As a result, a depletion layer spreads from the electric field relaxation region 56 to the JFET region 46. The depletion layer extending from the electric field relaxation region 56 to the JFET region 46 restricts electric field concentration at the lower end of each of the trenches 14. Therefore, the field effect transistor 10 can have a high breakdown voltage.

In addition, in the field effect transistor 10, the electric field relaxation region 56 is connected to the source electrode 22 by the pillar region 50 having a high p-type impurity concentration. That is, there is no region with a low p-type impurity concentration on the path from the electric field relaxation region 56 to the source electrode 22. Thus, the electrical resistance of the path from the electric field relaxation region 56 to the source electrode 22 is low. Therefore, during operation of the field effect transistor 10, the potential of the electric field relaxation region 56 is stabilized at approximately the same potential as that of the source electrode 22. That is, the potential of the electric field relaxation region 56 is unlikely to fluctuate while the field effect transistor 10 is in operation. Therefore, the width of the depletion layer extending from the electric field relaxation region 56 to the JFET region 46 can be changed with a high response speed in response to the operation of the field effect transistor 10.

Next, a manufacturing method of the field effect transistor 10 will be described. First, as shown in FIG. 5, a semiconductor substrate 12 having a lower n-type region 44, a body region 42, and an electric field relaxation region 56 is prepared. At this stage, the trenches 14 and the pillar regions 50 have not yet been formed in the semiconductor substrate 12. Each region shown in FIG. 5 may be formed by epitaxial growth or by ion implantation.

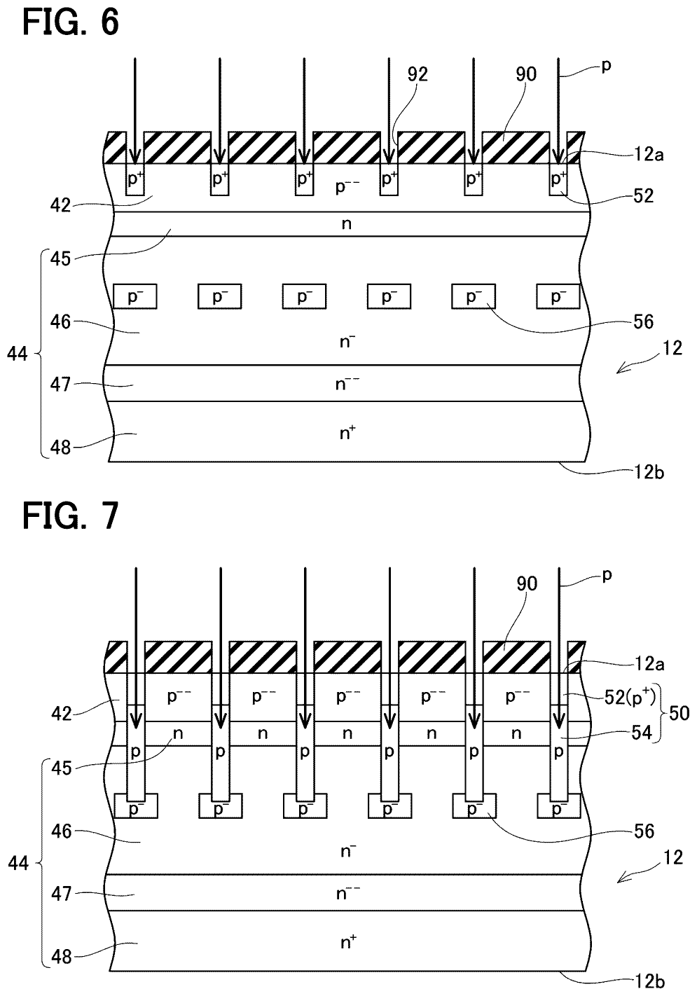

Next, as shown in FIG. 6, a mask 90 having opening portions 92 is formed on the upper surface 12a of the semiconductor substrate 12. The opening portions 92 are disposed above regions where the pillar regions 50 are to be formed. Next, a p-type impurity is ion-implanted into the semiconductor substrate 12 through the mask 90. In this process, the p-type impurity is implanted into a shallow region in the vicinity of the upper surface 12a at a high concentration. More specifically, the p-type impurity is implanted at a high concentration into a region shallower than the lower end of the body region 42. As a result, the contact region 52 is formed. Next, as shown in FIG. 7, a p-type impurity is ion-implanted into the semiconductor substrate 12 through the mask 90 common to that in FIG. 6. In this process, the p-type impurity is implanted into a range between the contact region 52 and the electric field relaxation region 56 (that is, a deeper position as viewed from the upper surface 12a) at a lower concentration than in the contact region 52. In this process, the p-type impurity is implanted at a concentration higher than the n-type impurity concentration in the current dispersion region 45. Accordingly, the connection region 54 is formed below the contact region 52. As a result, the pillar regions 50 are formed.

A graph G1 in FIG. 4 shows the concentration distribution of the p-type impurity implanted in the ion implantation processes shown in FIG. 6 and FIG. 7. In the graph G1, a concentration distribution of the p-type impurity implanted in the ion implantation process for forming the connection region 54 shown in FIG. 7 corresponds to a first concentration distribution. A graph G2 in FIG. 4 shows the concentration distribution of the p-type impurity in the electric field relaxation region 56 before the ion implantation processes shown in FIG. 6 and FIG. 7 are performed, and corresponds to a second concentration distribution. The distribution of the graph G3 is formed by adding the graph G1 and the graph G2. As shown by the graph G1, the p-type impurity implanted in the ion implantation processes is distributed such that the p-type impurity decreases downward (that is, toward the lower surface 12b) in a portion 54x located at the lower end of the implantation range. Furthermore, as shown by the graph G2, before the ion implantation processes, the electric field relaxation region 56 has at its upper end a portion 56x in which the p-type impurity concentration decreases upward (that is, toward the upper surface 12a. Since the portion 54x and the portion 56x overlap, the graph G1 and the graph G2 intersect. A p-type impurity concentration Dx1 at an intersection portion of the graph G1 and the graph G2 is higher than half the p-type impurity concentration Dc at the center position CP of the electric field relaxation region 56. Therefore, in the graph G3 obtained by adding the graph G1 and the graph G2, a p-type impurity concentration Dx2 at the intersection portion is higher than the p-type impurity concentration Dc at the center position CP. Therefore, as shown in the graph G3, the p-type impurity concentration becomes high over the entire path from the center position CP to the source electrode 22.

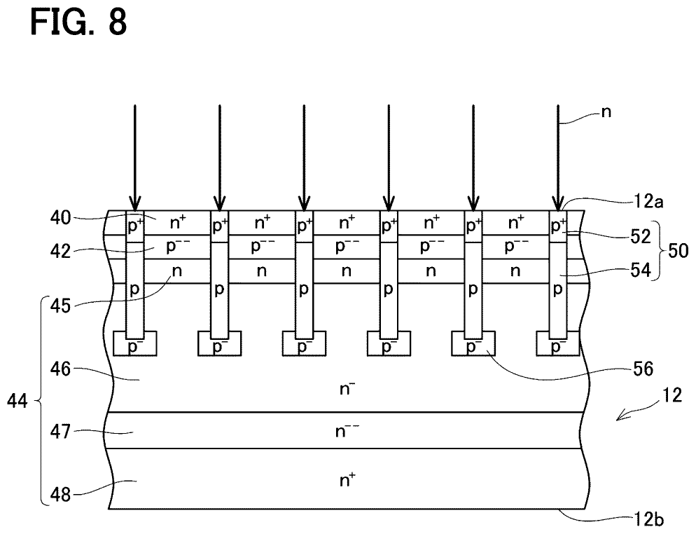

Next, as shown in FIG. 8, the mask 90 is removed, and the source region 40 is formed by ion-implanting an n-type impurity into a shallow region in the vicinity of the upper surface 12a. In this process, the n-type impurity is implanted into a region shallower than the lower end of the contact region 52 at a concentration lower than the p-type impurity concentration of the contact region 52 and higher than the p-type impurity concentration of the body region 42. Therefore, the shallow region of the body region 42 becomes n-type and becomes the source region 40, while the contact region 52 remains without being made n-type. Therefore, the boundary between the contact region 52 and the connection region 54 is located within a depth range below the source region 40 and above the lower end of the body region 42.

Thereafter, the trenches 14, the gate electrodes 18, the source electrode 22, the drain electrode 24, and the like are formed, thereby completing the field effect transistor 10 shown in FIGS. 1 to 3.

In the above-described manufacturing method, since the p-type impurity is implanted into the semiconductor substrate 12 at a high concentration in the process of forming the contact region 52, crystal defects are formed at a high density around the contact region 52. Since the contact region 52 is formed in the shallow region in the vicinity of the upper surface 12a, crystal defects are not formed at a high density in a deep position. Therefore, leakage current is less likely to occur in the field effect transistor 10 manufactured by this manufacturing method.

Furthermore, in the field effect transistor 10 manufactured by the above manufacturing method, the body region 42 is not interposed between the contact region 52 and the connection region 54, so that the electrical resistance between the electric field relaxation region 56 and the source electrode 22 is low. Therefore, the potential of the electric field relaxation region 56 can be stabilized. In particular, since the p-type impurity concentration is higher over the entire path from the center position CP of the electric field relaxation region 56 to the source electrode 22 than the p-type impurity concentration Dc at the center position CP, the potential of the electric field relaxation region 56 can be made more stable.

Furthermore, in the above-described manufacturing method, the contact region 52 and the connection region 54 are formed by ion implantation through the common mask 90, so that the contact region 52 and the connection region 54 can be formed efficiently. In the above-described embodiment, the contact region 52 is formed before the connection region 54. However, the contact region 52 may be formed after the connection region 54.

In the manufacturing method of the first embodiment described above, the electric field relaxation regions 56 are formed before the pillar regions 50 are formed. However, the electric field relaxation regions 56 may be formed after the pillar regions 50 are formed.

### Second Embodiment

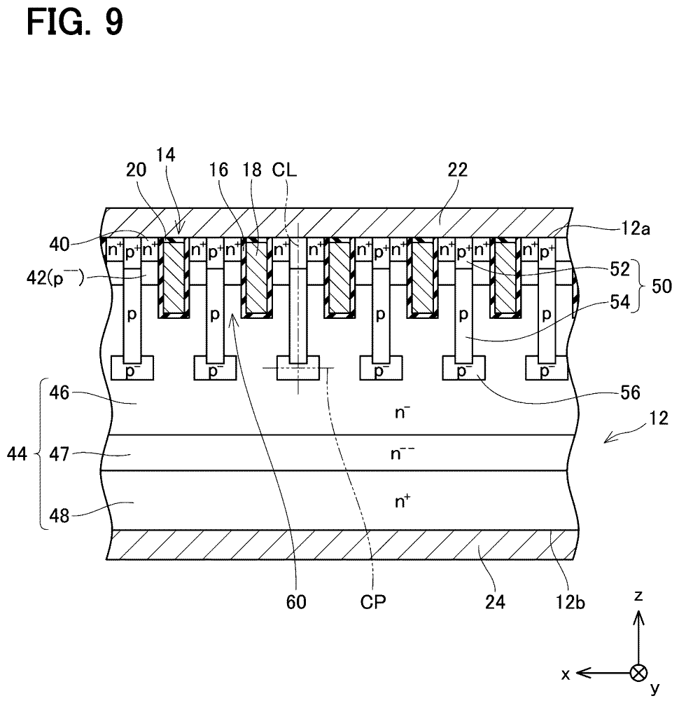

In the first embodiment described above, the lower n-type region 44 has the current dispersion region 45. However, in a field effect transistor 10 of a second embodiment, as shown in FIG. 9, the lower n-type region 44 may not have the current dispersion region 45, and the JFET region 46 may be in contact with the body region 42.

### Third Embodiment

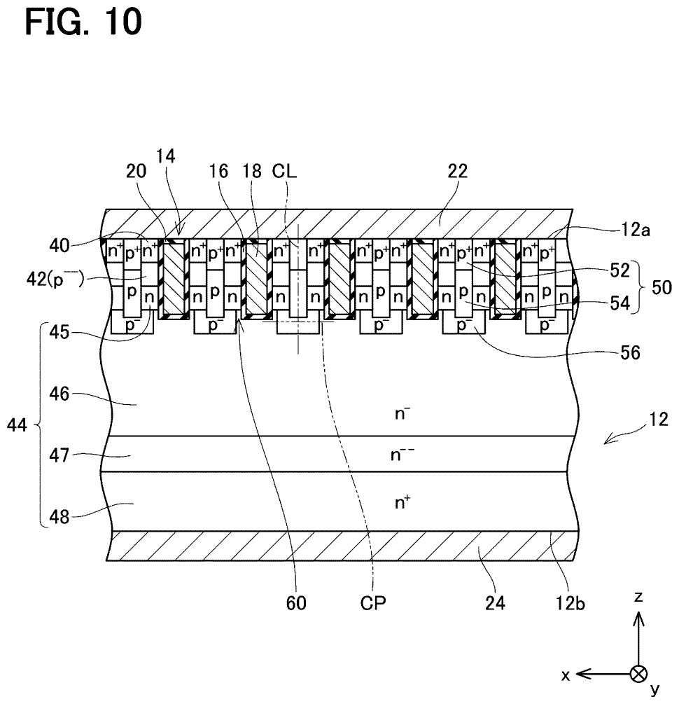

In the first embodiment described above, the electric field relaxation regions 56 are disposed below the lower ends of the trenches 14. However, in a field effect transistor 10 of a third embodiment, the electric field relaxation regions 56 may be disposed within a depth range including the lower ends of the trenches 14 as shown in FIG. 10.

### Fourth Embodiment

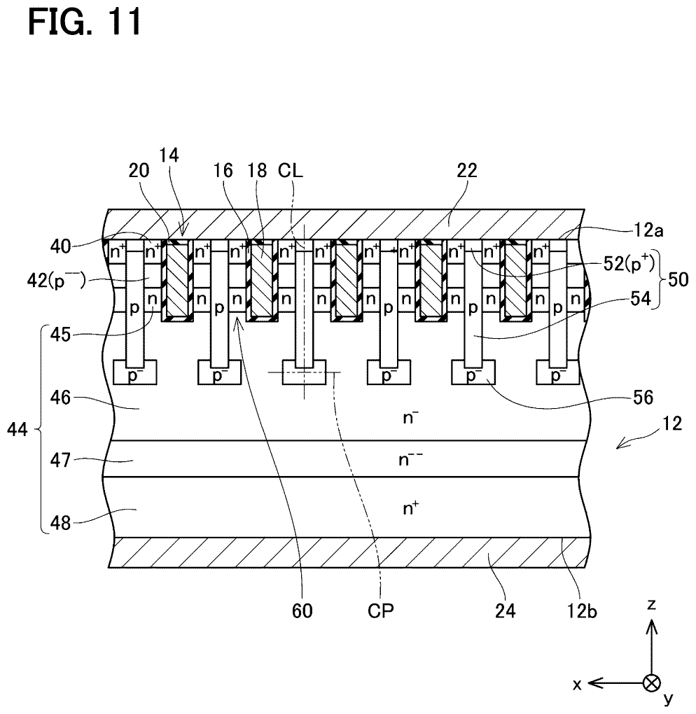

In the first embodiment described above, the interface between the contact region 52 and the connection region 54 is located within the depth range of the body region 42. However, in a field effect transistor 10 of a fourth embodiment, the interface between the contact region 52 and the connection region 54 may be located within a depth range of the source region 40 as shown in FIG. 11.

### Fifth Embodiment

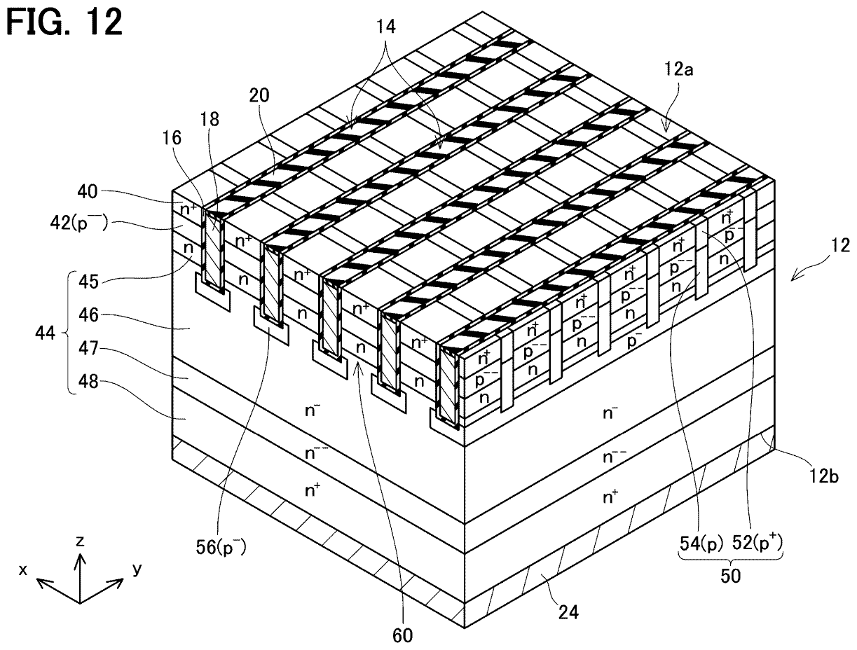

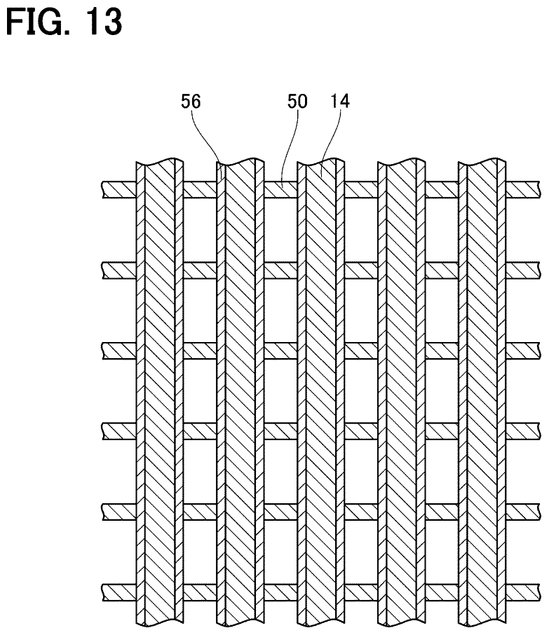

In the first embodiment described above, the electric field relaxation regions 56 are not in contact with the trenches 14. However, in a field effect transistor 10 of a fifth embodiment, the electric field relaxation regions 56 may be in contact with the lower ends of the respective trenches 14 as shown in FIG. 12 and FIG. 13. In this case, as shown in FIG. 12, the pillar regions 50 may extend linearly along the x direction (that is, the direction intersecting with the trenches 14). Even in this configuration, since the pillar regions 50 are disposed in each of the partitioned regions 60, the potential of each of the electric field relaxation regions 56 can be stabilized.

### Sixth Embodiment

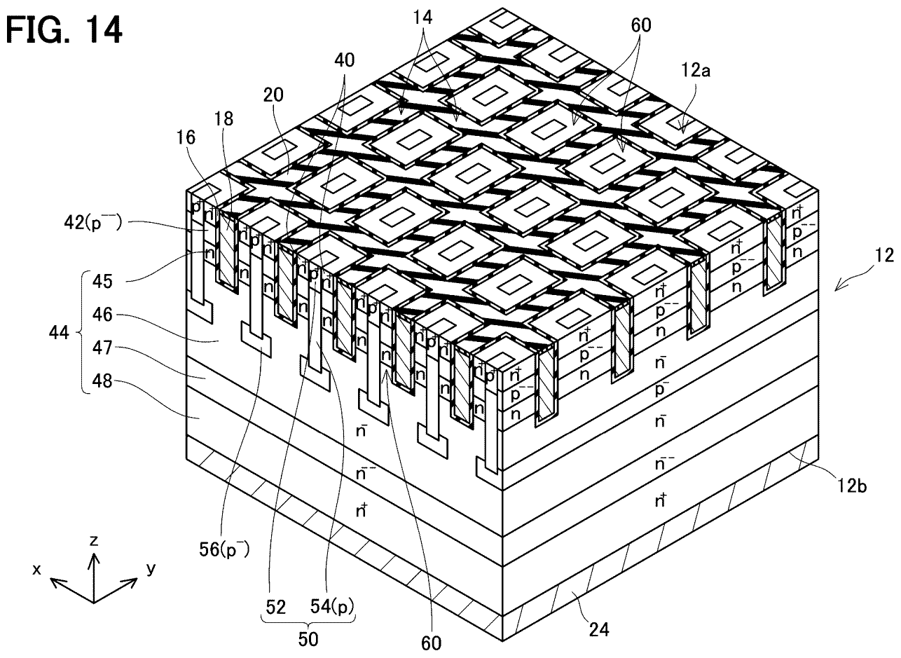

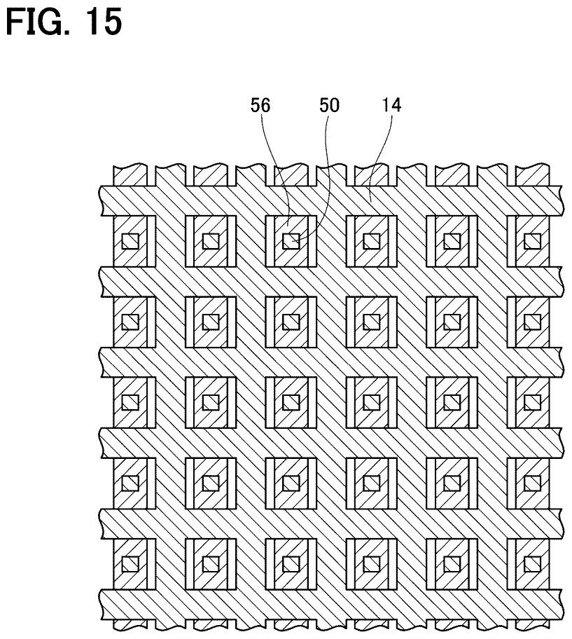

In the first embodiment described above, the trenches 14 extend linearly. However, in a field effect transistor 10 of a sixth embodiment, the trenches 14 may extend in a lattice shape as shown in FIG. 14 and FIG. 15. On the upper surface 12a of the semiconductor substrate 12, a plurality of rectangular partitioned regions 60 is formed. In this case, for example, the pillar regions 50 can be provided are the centers of the respective partitioned regions 60. Even in this configuration, since the pillar regions 50 are disposed in the respective partitioned regions 60, the potential of each of the electric field relaxation regions 56 can be stabilized.

### Seventh Embodiment

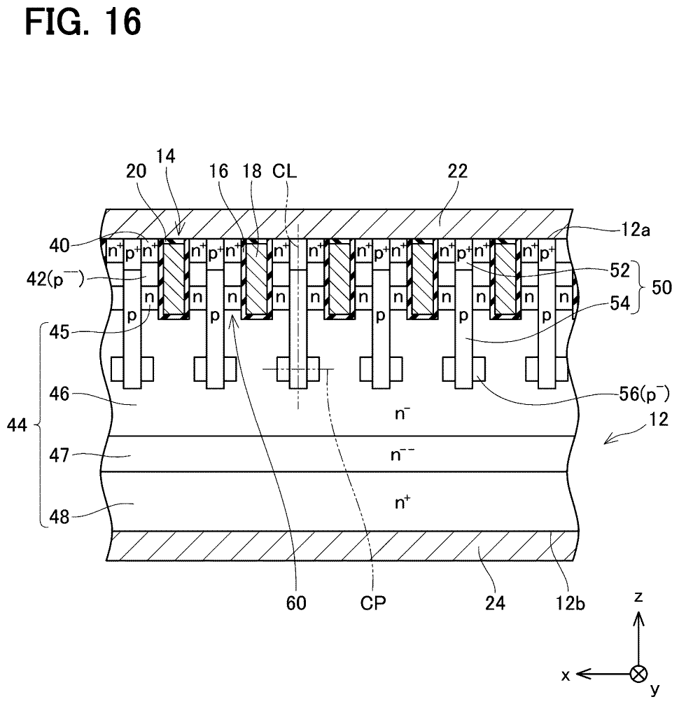

In a field effect transistor 10 of the seventh embodiment, as shown in FIG. 16, the connection regions 54 may pass through the respective electric field relaxation regions 56. However, it is easier to reduce the electric field concentration around the electric field relaxation regions 56 in the configuration where the connection regions 54 do not penetrate the electric field relaxation regions 56 as in FIG. 1 and FIG. 2.

The embodiments have been described in detail above, but these are merely examples and do not limit the scope of the claims. The technology described in the claims includes various modifications and changes to the specific examples described above. The technical elements described in the present specification or the drawings demonstrate technical utility either individually or in various combinations and are not limited to the combinations described in the claims at the time of filing. Furthermore, the technologies described in the present specification or the drawings achieve multiple objectives simultaneously, and achieving any one of these objectives alone demonstrates technical utility.

What is claimed is:

1. A field effect transistor comprising:
a semiconductor substrate having an upper surface and a lower surface opposite to the upper surface, and having at least one trench provided from the upper surface;
a gate insulating film and a gate electrode disposed in the at least one trench; and
a source electrode in contact with the upper surface of the semiconductor substrate, wherein
the semiconductor substrate includes:
a source region of n-type in contact with the gate insulating film and the source electrode;
a body region of p-type in contact with the gate insulating film at a position below the source region;
a lower n-type region in contact with the body region from below, in contact with the gate insulating film at a position below the body region, and extending to a position below a lower end of the at least one trench;
an electric field relaxation region of p-type disposed within a depth range including the lower end of the at least one trench or within a depth range below the lower end of the at least one trench, and in contact with the lower n-type region; and
a pillar region of p-type extending in a depth direction from a position in contact with the source electrode to a position in contact with the electric field relaxation region,
the pillar region includes:
a contact region of p-type disposed at a position in contact with the source electrode and having a p-type impurity concentration higher than a p-type impurity concentration of the body region; and
a connection region of p-type extending from a lower end of the contact region to a position in contact with the electric field relaxation region, and having a p-type impurity concentration that is lower than the p-type impurity concentration of the contact region and higher than the p-type impurity concentration of the body region, and
a boundary between the contact region and the connection region is located above a lower end of the body region.

2. The field effect transistor according to claim 1, wherein
in at least a part of a cross section, a width of the electric field relaxation region is greater than a width of the pillar region, and
a p-type impurity concentration on a path from a center position in a depth direction of the electric field relaxation region to the source electrode on a center line in a width direction of the pillar region is higher than a p-type impurity concentration at the center position.

3. The field effect transistor according to claim 1, wherein
the at least one trench includes a plurality of trenches provided from the upper surface of the semiconductor substrate,
the plurality of trenches partitions the semiconductor substrate into a plurality of semiconductor regions, and
the pillar region is disposed in each of the plurality of semiconductor regions.

4. The field effect transistor according to claim 1, wherein
the connection region does not penetrate through the electric field relaxation region.

5. The field effect transistor according to claim 1, wherein
the lower n-type region includes:
a first n-type region in contact with the body region from below; and
a second n-type region in contact with the first n-type region from below and having an n-type impurity concentration lower than an n-type impurity concentration of the first n-type region, and
the p-type impurity concentration of the connection region is higher than the n-type impurity concentration of the first n-type region.

6. The field effect transistor according to claim 1, wherein
within a depth range of the source region, a p-type impurity concentration of the pillar region is higher than an n-type impurity concentration of the source region.

7. A manufacturing method of a field effect transistor that includes:
a semiconductor substrate having an upper surface and a lower surface opposite to the upper surface, and having at least one trench provided from the upper surface;
a gate insulating film and a gate electrode disposed in the at least one trench; and
a source electrode in contact with the upper surface of the semiconductor substrate, wherein
the semiconductor substrate includes:
a source region of n-type in contact with the gate insulating film and the source electrode;
a body region of p-type in contact with the gate insulating film at a position below the source region;
a lower n-type region in contact with the body region from below, in contact with the gate insulating film at a position below the body region, and extending to a position below a lower end of the at least one trench;
an electric field relaxation region of p-type disposed within a depth range including the lower end of the at least one trench or within a depth range below the lower end of the at least one trench, and in contact with the lower n-type region; and
a pillar region of p-type extending in a depth direction from a position in contact with the source electrode to a position in contact with the electric field relaxation region,
the pillar region includes:
a contact region of p-type disposed at a position in contact with the source electrode and having a p-type impurity concentration higher than a p-type impurity concentration of the body region; and
a connection region of p-type extending from a lower end of the contact region to a position in contact with the electric field relaxation region, and having a p-type impurity concentration that is lower than the p-type impurity concentration of the contact region and higher than the p-type impurity concentration of the body region, and
a boundary between the contact region and the connection region is located above a lower end of the body region,
the manufacturing method comprising:
forming the contact region by implanting a p-type impurity into the semiconductor substrate through a mask; and
forming the connection region by implanting a p-type impurity into the semiconductor substrate through the mask that is used for the forming of the contact region.

8. The manufacturing method according to claim 7, wherein
a concentration distribution of the p-type impurity implanted in the forming of the connection region is a first concentration distribution,
a concentration distribution of a p-type impurity in the electric field relaxation region is a second concentration distribution,
a portion in the first concentration distribution in which a concentration of the p-type impurity decreases toward the lower surface overlaps a portion in the second concentration distribution in which a concentration of the p-type impurity decreases toward the upper surface, and
a p-type impurity concentration at an intersection portion where the first concentration distribution and the second concentration distribution intersect is higher than half a p-type impurity concentration at a center position in a depth direction of the electric field relaxation region.
